(19) United States
(12) Patent Application Publication
(10) Pub. No.: US 2023/0236582 A1
(43) Pub. Date: Jul. 27, 2023

(54) METHOD FOR FACILITATING DISMANTLING A PHOTOVOLTAIC MODULE

(71) Applicants: TAIWAN SOLAR GREENERGY CORPORATION, Tainan City (TW); TSGC TECHNOLOGIES INC., Tainan City (TW)

(72) Inventors: Yao-Hsien Fu, Kaohsiung City (TW); Chia-Tsung Hung, Tainan City (TW)

(21) Appl. No.: 17/829,931

(22) Filed: Jun. 1, 2022

(30) Foreign Application Priority Data
Jan. 26, 2022 (TW) 111103332

(51) Int. Cl. G05B 19/418; H02S 30/10; G06K 19/06

(52) U.S. Cl. CPC G05B 19/4183; H02S 30/10; G06K 19/06009

(57) ABSTRACT

A method for facilitating dismantling of a photovoltaic module includes steps of: obtaining, by an input module, product data of the photovoltaic module from a module information indicator provided on the photovoltaic module; retrieving, by a processor, a product identification code of the photovoltaic module by matching the product data against a database; generating, by an equipment controller, a control command based on the product identification code; and sending, by the equipment controller, the control command to a dismantling equipment to set equipment configuration parameters for the dismantling equipment to dismantle the photovoltaic module.

### CROSS-REFERENCE TO RELATED APPLICATION

This application claims priority to Taiwanese Invention Patent Application No. 111103332, filed on Jan. 26, 2022.

### FIELD

The disclosure relates to recycling of a photovoltaic module, and more particularly to a method for facilitating dismantling a photovoltaic module.

### BACKGROUND

A photovoltaic module includes a photovoltaic panel, a cover plate and a back plate which are disposed on opposite sides of the photovoltaic panel, junction box(es) which is/are disposed on the back plate, two glue layers each of which is sandwiched between the photovoltaic panel and a respective one of the cover plate and the back plate, and a frame which frames the photovoltaic panel, the cover plate and the back plate.

In the solar photovoltaic industry, a photovoltaic module qualified for sale must meet relevant standards published by the International Electrotechnical Commission (IEC), such as IEC 61215 which lays down requirements for the design qualification and type approval of terrestrial photovoltaic modules, and IEC 61730 which defines photovoltaic module safety qualification. These standards are applicable world-wide, but to be sold in individual countries, the photovoltaic module still needs to be certified by a certification institute, registered in a local regulatory authority (e.g., Bureau of Energy), and provided with a discernable label indicting an identification code. However, since local regulatory authorities of different countries have their own databases, and their distinct ways of defining the identification codes for the labels, there is no universal specifications for the identification codes.

In the processes of dismantling and recycling a photovoltaic module, parameters related to the photovoltaic module must be determined and set individually in a module dismantling apparatus based on a model number or form factors of the photovoltaic module. Such processes are labor-intensive and time consuming and hence lead to higher operating cost.

### SUMMARY

Therefore, an object of the disclosure is to provide a method for facilitating the dismantling of a photovoltaic module that can alleviate at least one of the drawbacks of the prior art.

According to an aspect of the disclosure, the method for facilitating the dismantling of a photovoltaic module is to be implemented by a disassemble system. The photovoltaic module is provided with a module information indicator. The disassemble system includes an identification apparatus and a module dismantling apparatus connected to the identification apparatus. The identification apparatus includes an input module, a processor and a storage medium which stores a photovoltaic module database. The module dismantling apparatus includes an equipment controller and a dismantling equipment which is connected to the equipment controller. The method includes:

by the input module, obtaining product data of the photovoltaic module from the module information indicator;

by the processor after receiving the product data from the input module, retrieving a product identification code of the photovoltaic module by matching the product data against the photovoltaic module database stored in the storage medium;

by the equipment controller after receiving the product identification code from the processor, generating a control command based on the product identification code; and by the equipment controller, sending the control command to the dismantling equipment to set equipment configuration parameters for the dismantling equipment to dismantle the photovoltaic module.

### BRIEF DESCRIPTION OF THE DRAWINGS

Other features and advantages of the disclosure will become apparent in the following detailed description of the embodiment(s) with reference to the accompanying drawings, of which:

FIG. 1 is a schematic diagram illustrating a photovoltaic module to be dismantled and recycled according to an embodiment of the disclosure;

FIG. 2 is a schematic diagram illustrating a disassemble system according to an embodiment of the disclosure;

FIG. 3 is a schematic diagram illustrating an input module which optically detects a module information indicator provided on the photovoltaic module according to an embodiment of the disclosure; and

FIG. 4 is a flow chart illustrating a method for facilitating dismantling a photovoltaic module according to an embodiment of the disclosure.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

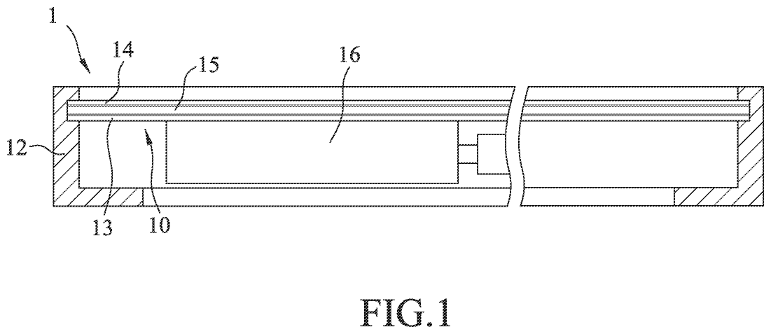

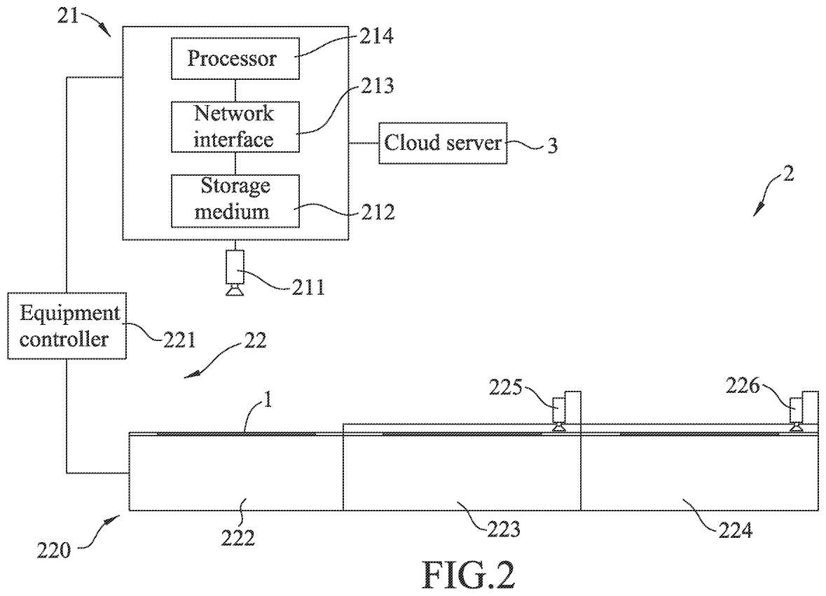

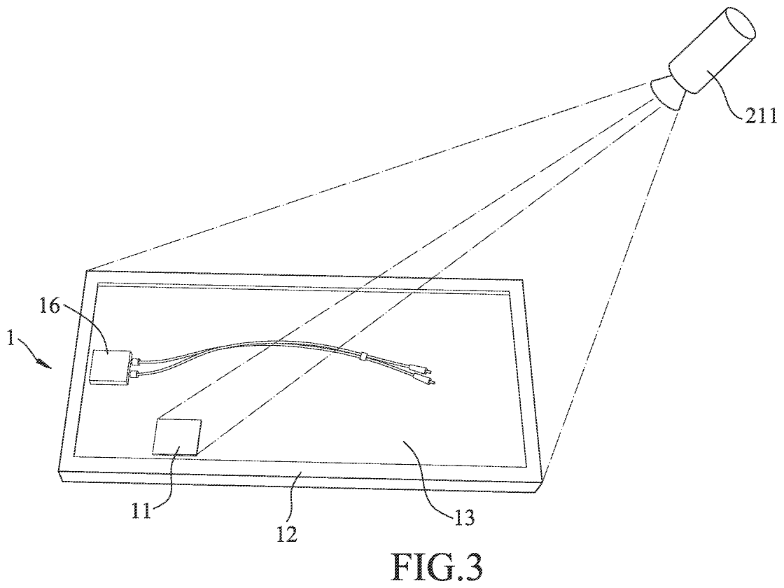

Referring to FIGS. 1 to 3, a disassemble system 2 according to an embodiment of the disclosure is used to dismantle a photovoltaic module 1. The photovoltaic module 1 includes a photovoltaic unit 10 which includes a back plate 13 and a cover plate 14 opposite to each other, at least one junction box 16 which is disposed on the back plate 13, and a frame 12 which frames the photovoltaic unit 10. The photovoltaic unit 10 further includes a photovoltaic panel 15 which is composed of photovoltaic cells and which is sandwiched between the back plate 13 and the cover plate 14. The photovoltaic module 1 is provided with a module information indicator 11 disposed on the back plate 13. It is noted that the module information indicator 11 may have different forms depending on different requirements and different sales regions. For example, the module information indicator 11 includes one of a text label, a graphic label, a digital watermark, a barcode, and combinations thereof. The barcode may be a one-dimensional barcode, a two-dimensional barcode and/or a three-dimensional barcode. In this embodiment, a location of placement of the module information indicator 11 is exemplified to be near a corner of the back plate 13 (see FIG. 3). However, the location of placement of the module information indicator 11 is not limited to the disclosure herein, and may be anywhere on the photovoltaic module 1.

The disassemble system 2 includes an identification apparatus 21, and a module dismantling apparatus 22 which is connected to the identification apparatus 21. The identification apparatus 21 includes an input module 211, a network interface 213, a processor 214, and a storage medium 212 which stores a photovoltaic module database. The module dismantling apparatus 22 includes an equipment controller 221 and a dismantling equipment 220 which is connected to the equipment controller 221. The dismantling equipment 220 of the module dismantling apparatus 22 includes a frame removal device 222, a back plate removal device 223 downstream of the frame removal device 222, and a cover plate removal device 224 downstream of the back plate removal device 223.

The identification apparatus 21 analyzes the module information indicator 11 of the photovoltaic module 1 to generate a product identification code, and provides the product identification code to the equipment controller 221. The equipment controller 221, in response to receipt of the product identification code, sets equipment configuration parameters for the dismantling equipment 220 to dismantle the photovoltaic module 1 which is disposed on the module dismantling apparatus 22. The equipment configuration parameters include frame removal parameters for the frame removal device 222, back plate removal parameters for the back plate removal device 223, and cover plate removal parameters for the cover plate removal device 224. In some embodiments, the equipment controller 221 may be implemented by a microcontroller.

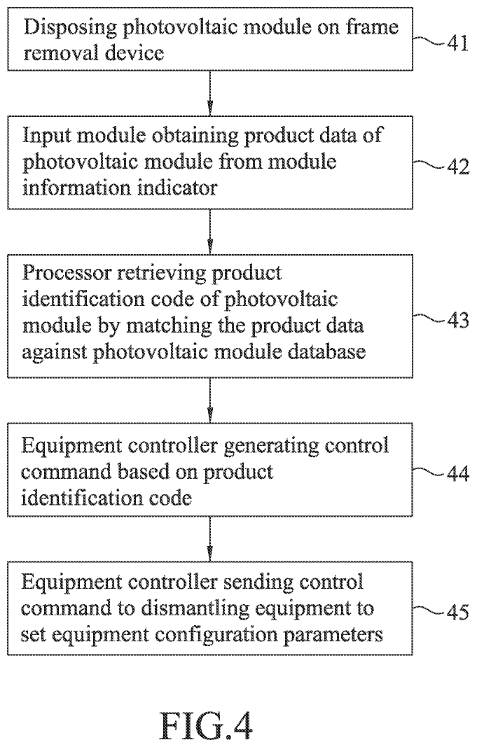

Referring to FIG. 4, a method for facilitating dismantling of a photovoltaic module according to an embodiment of the disclosure is illustrated. The method is to be implemented by the disassemble system 2 describe above. The method includes steps 41 to 45 which are delineated hereinafter.

In step 41, the photovoltaic module 1 to be dismantled is disposed on the frame removal device 222 of the dismantling equipment 220 of the module dismantling apparatus 22.

In step 42, the input module 211 obtains product data of the photovoltaic module 1 from the module information indicator 11, and provides the product data to the processor 214. Specifically, the input module 211 optically detects the module information indicator 11 provided on the photovoltaic module 1, and analyzes the module information indicator 11 thus detected to obtain the product data. In some embodiments, the module information indicator 11 contains information related to a manufacturer, a product serial number, maximum power, a certification institute, dimensions, weight, etc., of the photovoltaic module 1. In some embodiments, the product data includes the information contained in the module information indicator 11. In some embodiments where the module information indicator 11 is a text label, a graphic label and/or a digital watermark, the input module 211 includes a camera and a microprocessor. The camera captures an image of the module information indicator 11, and the microprocessor extracts information from the image by performing optical character recognition (OCR), image analysis, and/or pattern recognition on the image to obtain the product data of the photovoltaic module 1. In some embodiments where the module information indicator 11 is a barcode, the input module 211 includes a barcode reader and a microprocessor. The barcode reader scans the module information indicator 11, and the microprocessor extracts information from the barcode by decoding the barcode scanned by the barcode reader to obtain the product data of the photovoltaic module 1. In some embodiments, the input module 211 may include an optical measuring machine and a weighing machine that measure dimensions (including the thicknesses of the cover plate 14 and the back plate 13), and a weight of the photovoltaic module 1, respectively, to obtain a part of the product data of the photovoltaic module.

In step 43, after receiving the product data from the input module 211, the processor 214 retrieves a product identification code of the photovoltaic module 1 by matching the product data against the photovoltaic module database stored in the storage medium 212, and transmits the product identification code to the equipment controller 221 of the module dismantling apparatus 22. The photovoltaic module database is an organized collection of plural pieces of product data that correspond to various models of photovoltaic modules, and each of the various models of photovoltaic modules is assigned a unique product identification code in advance in the photovoltaic module database. In some embodiments, the processor 214 may be implemented by a central processing unit (CPU), and the storage medium 212 may be implemented by a computer memory, such as flash memory, a hard disk drive or a solid-state drive.

In some embodiments, the network interface 213 of the identification apparatus 21 is connected to a cloud server 3 which stores a cloud database that contains organized collection of data related to different models of photovoltaic modules and that may be updated frequently. The network interface 213 may be implemented by a network interface controller, a network interface card or a network adaptor. The processor 214, after retrieving the product identification code of the photovoltaic module 1, confirms validity of the product identification code by transmitting the product data via the network interface 213 to the cloud sever 3 to match the product data against the cloud database so as to retrieve a reference identification code, and comparing the product identification code and the reference identification code. In some embodiments, the processor 214 updates the photovoltaic module database stored in the storage medium 212 by referring to, via the network interface 213, the cloud database stored in the cloud server 3.

In step 44, after receiving the product identification code from the processor 214, the equipment controller 221 generates a control command based on the product identification code. In some embodiments, the equipment controller 221 may refer to a lookup table that is established in advance and that is stored in the module dismantling apparats 22. The lookup table records plural sets of parameters which respectively correspond to multiple product identification codes, and each of which is related to configuration of the dismantling equipment 220 for dismantling a specific model of photovoltaic module assigned the respective one of the product identification codes. Accordingly, the equipment controller 221 is able to look up the set of parameters corresponding to the product identification code in the lookup table, and to generate the control command indicating the set of parameters.

In step 45, the equipment controller 221 sends the control command to the dismantling equipment 220 to set equipment configuration parameters for the dismantling equipment 220 to dismantle the photovoltaic module 1, Specifically, the equipment controller 221 sends the control command to the dismantling equipment 220 to set the frame removal parameters for the frame removal device 222, to set the back plate removal parameters for the back plate removal device 223, and to set the cover plate removal parameters for the cover plate removal device 224.

In some embodiments, the dismantling equipment 220 further includes a back plate remover 225 that is connected to the back plate removing device 223, and a cover plate remover 226 that is connected to the cover plate removing device 224. After the frame removal parameters for the frame removal device 222 have been set, the frame removal device 222 removes the frame 12 of the photovoltaic module 1 based on the frame removal parameters. In some embodiments, the frame removal device 222 may remove the at least one junction box 16 together with the frame 12. After the back plate removal parameters for the back plate removal device 223 have been set, the back plate removal device 223 controls, based on the back plate removal parameters, the back plate remover 225 to remove the back plate 13 of the photovoltaic module 1. After the cover plate removal parameters for the cover plate removal device 224 have been set, the cover plate removal device 224 controls, based on the cover plate removal parameters, the cover plate remover 226 to remove the cover plate 14 of the photovoltaic module 1. In some embodiments, the back plate remover 225 and the cover plate remover 226 may include robotic arms, and the back plate removal device 223 and the cover plate removal device 224 may include microcontrollers (not shown) which control operations of the robotic arms of the back plate remover 225 and the cover plate remover 226, respectively.

In some embodiments, the frame removal parameters include values of dismantling pressures, a displacement extent for removing the frame 12, and a position of the at least one junction box 16; the back plate removal parameters include a value of thickness and material composition of the back plate 13 and further include a value of rotational speed, a value of moving speed and a moving path for the back plate remover 225; the cover plate removal parameters include a value of thickness and material composition of the cover plate 14 and further include a value of rotational speed, a value of moving speed and a moving path for the cover plate remover 226.

It is noted that in the example shown in FIG. 4, the photovoltaic module 1 is disposed on the frame removal device 222 of the module dismantling apparatus 22 in step 41 prior to the steps of obtaining the product data, retrieving the product identification code, generating the control command and setting the equipment configuration parameters. However, in other embodiments, the photovoltaic module 1 is only required to be disposed on the frame removal device 222 before the frame removal device 222 removes the frame 12 and the at least one junction box 16 of the photovoltaic module 1. In other words, the photovoltaic module 1 is not necessarily disposed on the frame removal device 222 while the input module 211 obtains the product data of the photovoltaic module 1, and the photovoltaic module 1 may be disposed anywhere for the product data to be obtained, as long as the processor 214 can receive the product data and retrieve the product identification code of the photovoltaic module 1 based on the product data.

To sum up, by virtue of the input module 211 which obtains the product data of the photovoltaic module 1 from the module information indicator 11 and the processor 214 which matches the product data against the photovoltaic module database, the identification code dedicated to the photovoltaic module 1 may be retrieved. Moreover, the equipment controller 221 generates the control command based on the product identification code, and sends the control command to the dismantling equipment 220 to set the frame removal parameters for the frame removal device 222, to set the back plate removal parameters for the back plate removal device 223, and to set the cover plate removal parameters for the cover plate removal device 224 for dismantling the photovoltaic module 1. As a result, human labor and working time required to determine product data of a photovoltaic module and to set the equipment configuration parameters for the dismantling equipment 220 in order to dismantle that photovoltaic module may be saved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what is (are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A method for facilitating dismantling of a photovoltaic module (1), the method to be implemented by a disassemble system (2), the photovoltaic module (1) provided with a module information indicator (11), the disassemble system (2) including an identification apparatus (21) and a module dismantling apparatus (22) connected to the identification apparatus (21), the identification apparatus (21) including an input module (211), a processor (214) and a storage medium (212) which stores a photovoltaic module database, the module dismantling apparatus (22) including an equipment controller (221) and a dismantling equipment (220) which is connected to the equipment controller (221), the method comprising:
by the input module (211), obtaining product data of the photovoltaic module (1) from the module information indicator (11);
by the processor (214) after receiving the product data from the input module (211), retrieving a product identification code of the photovoltaic module (1) by matching the product data against the photovoltaic module database stored in the storage medium (212);
by the equipment controller (221) after receiving the product identification code from the processor (214), generating a control command based on the product identification code; and
by the equipment controller (221), sending the control command to the dismantling equipment (220) to set equipment configuration parameters for the dismantling equipment (220) to dismantle the photovoltaic module (1).

2. The method as claimed in claim 1, the identification apparatus (21) further including a network interface (213) connected to a cloud server (3) which stores a cloud database that contains organized collection of data related to different models of photovoltaic modules, the method further comprising:
by the processor (214) after retrieving the product identification code of the photovoltaic module (1), confirming validity of the product identification code by transmitting the product data via the network interface (213) to the cloud sever (3) to match the product data against the cloud database.

3. The method as claimed in claim 2, further comprising:
by the processor (214), updating the photovoltaic module database stored in the storage medium (212) by referring to, via the network interface (213), the cloud database stored in the cloud server (3).

4. The method as claimed in claim 1, wherein obtaining product data includes:
optically detecting the module information indicator (11) provided on the photovoltaic module (1); and
analyzing the module information indicator (11) thus detected to obtain the product data.

5. The method as claimed in claim 1, wherein obtaining product data includes:
obtaining the product data of the photovoltaic module (1) from the module information indicator (11), which includes one of a text label, a graphic label, a digital watermark, a barcode, and combinations thereof.

6. The method as claimed in claim 1, the dismantling equipment (220) of the module dismantling apparatus (22) including a frame removal device (222), a back plate removal device (223) and a cover plate removal device (224), wherein the step of sending the control command to set equipment configuration parameters includes sending the control command to the dismantling equipment (220) to:
set frame removal parameters for the frame removal device (222);
set back plate removal parameters for the back plate removal device (223); and
set cover plate removal parameters for the cover plate removal device (224).

7. The method as claimed in claim 6, the photovoltaic module (1) being disposed on the dismantling equipment (220), and including a back plate (13), at least one junction box (16) on the back plate (13), a cover plate (14), and a frame (12) that frames the back plate (13) and the cover plate (14), the dismantling equipment (220) further including a back plate remover (225) that is connected to the back plate removing device (223) and a cover plate remover (226) that is connected to the cover plate removing device (224), the method further comprising:
by the frame removal device (222), removing the frame (12) and the at least one junction box (16) of the photovoltaic module (1) based on the frame removal parameters;
by the back plate removal device (223) based on the back plate removal parameters, controlling the back plate remover (225) to remove the back plate (13) of the photovoltaic module (1); and
by the cover plate removal device (224) based on the cover plate removal parameters, controlling the cover plate remover (226) to remove the cover plate (14) of the photovoltaic module (1).

8. The method as claimed in claim 7, wherein:
the frame removal parameters include values of dismantling pressures, a displacement extent and a position of the at least one junction box (16) for removing the frame (12) and the at least one junction box (16);
the back plate removal parameters include a value of thickness and material composition of the back plate (13) and further include a value of rotational speed, a value of moving speed and a moving path for the back plate remover (225); and
the cover plate removal parameters include a value of thickness and material composition of the cover plate (14) and further include a value of rotational speed, a value of moving speed and a moving path for the cover plate remover (226).
